(19) United States
(12) Patent Application Publication
(10) Pub. No.: US 2026/0006707 A1
(43) Pub. Date: Jan. 1, 2026

(54) CONTROL APPARATUS AND LIGHT SOURCE APPARATUS

(71) Applicant: Lasertec Corporation, Yokohama (JP)

(72) Inventors: Shinji TANAKA, Yokohama-shi (JP); Masaki KOICHI, Yokohama-shi (JP)

(21) Appl. No.: 19/253,353

(22) Filed: Jun. 27, 2025

(30) Foreign Application Priority Data
Jun. 27, 2024 (JP) 2024-103905

(51) Int. Cl. H05G 2/00; G03F 7/00

(52) U.S. Cl. CPC H05G 2/0082; G03F 7/70033; H05G 2/0035; H05G 2/0094

(57) ABSTRACT

A control apparatus for an optical apparatus including a light source apparatus according to the present disclosure is configured to determine a mode to be executed from among a plurality of modes and control the optical apparatus accordingly. The plurality of modes include a first mode in which the light source apparatus irradiates laser light onto a molten target material to generate illumination light, and the optical apparatus illuminates an object using the illumination light, and a second mode in which the light source apparatus irradiates laser light onto at least one of a holding unit of the target material or the target material in a solid state to change the target material from the solid state to a molten state.

### INCORPORATION BY REFERENCE

This application is based upon and claims the benefit of priority from Japanese patent application No. 2024-103905, filed on Jun. 27, 2024, the disclosure of which is incorporated herein in its entirety by reference for all purposes.

### BACKGROUND

The present disclosure relates to a control apparatus, a light source apparatus, a control method, and a non-transitory computer readable medium.

Patent Literature 1 discloses a light source that emits illumination light by forming a target material on a surface of a cylindrical member rotating around a rotation axis and irradiating the formed target material with excitation light. Patent Literature 2 discloses a light source that emits illumination light by holding a target material made of molten metal on the inner wall of a crucible rotating around a rotation axis by a centrifugal force and irradiating the held target material with excitation light.
Patent Literature 1: Japanese Unexamined Patent Application Publication No. 2020-077007
Patent Literature 2: Japanese Unexamined Patent Application Publication No. 2022-168463

### SUMMARY

An example of an object to be achieved by the present disclosure is to provide a control apparatus, a light source apparatus, a control method, and a program capable of improving the efficiency of the operation and maintenance of an apparatus. It should be noted that this object is only one of a plurality of objects to be achieved by a plurality of embodiments disclosed herein. Other objects or problems and new characteristics are clarified from the description of the present specification and the accompanying drawings.

A control apparatus according to the present disclosure is a control apparatus for an optical apparatus including a light source apparatus, configured to determine a mode to be executed from among a plurality of modes and control the optical apparatus accordingly. The plurality of modes include a first mode in which the light source apparatus irradiates laser light onto a molten target material to generate illumination light, and the optical apparatus illuminates an object using the illumination light, and a second mode in which the light source apparatus irradiates laser light onto at least one of a holding unit of the target material or the target material in a solid state to change the target material from the solid state to a molten state.

The control apparatus according to the present disclosure is a control apparatus for a light source apparatus, configured to determine a mode to be executed from among a plurality of modes and control the light source apparatus accordingly. The plurality of modes include a first mode in which the light source apparatus irradiates laser light onto a molten target material to generate light and a second mode in which the light source apparatus irradiates laser light onto at least one of a holding unit of the target material or the target material in a solid state to change the target material from the solid state to a molten state.

A peak power density of the laser light in the second mode may be smaller than that of the laser light in the first mode.

An irradiation state of the laser light in the second mode may be a defocus state compared to that of the laser light in the first mode.

Peak power of the laser light in the second mode may be smaller than that of the laser light in the first mode.

When the mode to be executed is the second mode, the above-described control apparatus may switch the mode to be executed from the second mode to the first mode based on a fact that a position of plasma generated by the irradiation of the laser light coincides with a predetermined position.

When the mode to be executed is the second mode, the above-described control apparatus may switch the mode to be executed from the second mode to the first mode based on determination that the target material has been melted.

The above-described light source apparatus may include a laser generator configured to output the laser light in the first mode and the laser light in the second mode. The above-described control apparatus may control the laser generator according to the mode to be executed.

The above-described light source apparatus may include: a first laser generator configured to output the laser light in the first mode; a second laser generator configured to output the laser light in the second mode; and an optical element through which the laser light generated by the first laser generator and the laser light generated by the second laser generator pass. The above-described control apparatus may control the first and second laser generators according to the mode to be executed.

The above-described light source apparatus may include the holding unit configured to hold the molten target material by rotating. The above-described control apparatus may make the light source apparatus irradiate the molten target material held by the holding unit with the laser light when the mode to be executed is the first mode.

The above-described optical apparatus may include adjustment means for preventing light generated in the light source apparatus from propagating to the object. The above-described control apparatus may drive the adjustment means when the mode to be executed is the second mode.

A light source apparatus according to the present disclosure is a light source apparatus configured to generate light by irradiating a molten target material with laser light. The above-described light source apparatus includes a control unit configured to change the target material from a solid state to a molten state by irradiating at least one of a holding unit of the target material or the target material in the solid state with laser light.

The above-described light source apparatus may further include the holding unit configured to hold the molten target material by rotating.

A method for controlling an optical apparatus according to the present disclosure includes: a first step of illuminating an object with illumination light generated by irradiating a molten target material with laser light; a second step of changing the target material from a solid state to a molten state by irradiating at least one of a holding unit of the target material or the target material in the solid state with laser light; and a third step of switching the first step and the second step.

A method for controlling a light source apparatus according to the present disclosure includes: a first step of generating light by irradiating a molten target material with laser light; a second step of changing the target material from a solid state to a molten state by irradiating at least one of a holding unit of the target material or the target material in the solid state with laser light; and a third step of switching the first step and the second step.

A program according to the present disclosure causes an optical apparatus to perform: a first step of illuminating an object with illumination light generated by irradiating a molten target material with laser light; a second step of changing the target material from a solid state to a molten state by irradiating at least one of a holding unit of the target material or the target material in the solid state with laser light; and a third step of switching the first step and the second step.

A program according to the present disclosure causes a light source apparatus to perform: a first step of generating light by irradiating a molten target material with laser light; a second step of changing the target material from a solid state to a molten state by irradiating at least one of a holding unit of the target material or the target material in the solid state with laser light; and a third step of switching the first step and the second step.

According to the present disclosure, it is possible to improve the efficiency of the operation and maintenance of an apparatus.

The above and other objects, features and advantages of the present disclosure will become more fully understood from the detailed description given hereinbelow and the accompanying drawings.

### BRIEF DESCRIPTION OF DRAWINGS

FIG. 1 is a cross-sectional diagram showing an example of a light source apparatus according to a first embodiment;

FIG. 2 is a perspective view showing an example of a container, which serves as a target holding unit, in the light source apparatus according to the first embodiment;

FIG. 3 is a plan view showing the example of the light source apparatus according to the first embodiment;

FIG. 4 shows an example of a focus adjusting mechanism according to the first embodiment;

FIG. 5 shows an example of an acquisition unit, a driving unit, and a control unit in the light source apparatus according to the first embodiment;

FIG. 6 is a flowchart showing an example of a method for controlling an operation mode according to the first embodiment; and

FIG. 7 is a configurational diagram showing an example of an inspection apparatus including the light source apparatus according to the first embodiment.

### DESCRIPTION OF EMBODIMENTS

A specific configuration of an embodiment is explained below with reference to the drawings. The following explanation indicates a preferred embodiment of the present disclosure. The scope of the present disclosure is not limited to the embodiment explained below. In the following explanation, those with the same reference numerals and signs indicate substantially the same content.

### First Embodiment

A light source apparatus according to a first embodiment is explained. The light source apparatus according to the present embodiment generates light such as illumination light and exposure light used for an optical apparatus such as an inspection apparatus and an exposure apparatus. The light source apparatus may be provided integrally with the optical apparatus or may be disposed near the optical apparatus as a separate body separated from the optical apparatus. When the optical apparatus is the inspection apparatus, the light source apparatus generates illumination light for illuminating an inspection target in the inspection apparatus. When the optical apparatus is the exposure apparatus, the light source apparatus generates exposure light for exposing an exposure target in the exposure apparatus.

The light source apparatus irradiates a target material held by a target holding unit with excitation light to thereby generate light such as illumination light and exposure light. In the first embodiment explained below, as an example of the light source apparatus, an example in which a liquid target material is held in a target holding unit including a container such as a crucible is explained. However, the target holding unit may include a cylindrical drum, a tape-like structure, or the like rather than the container such as a crucible. For example, a solid target material is held in the drum. As another example, the light source apparatus may use a tape-like target material or may use a target material dripped or spouted in a droplet shape. That is, the target holding unit is not always necessary in the configuration of the light source apparatus.

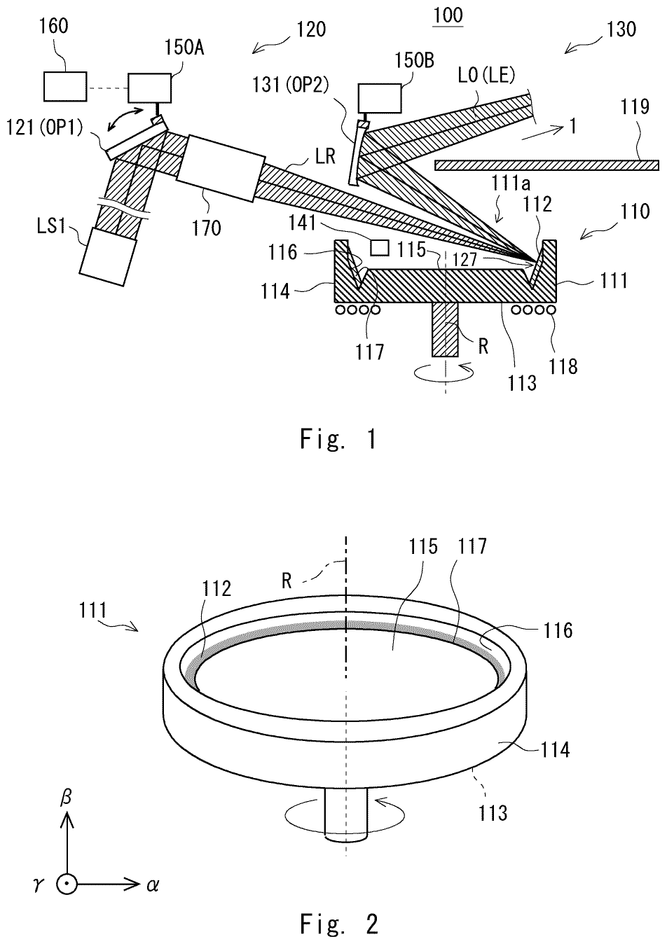

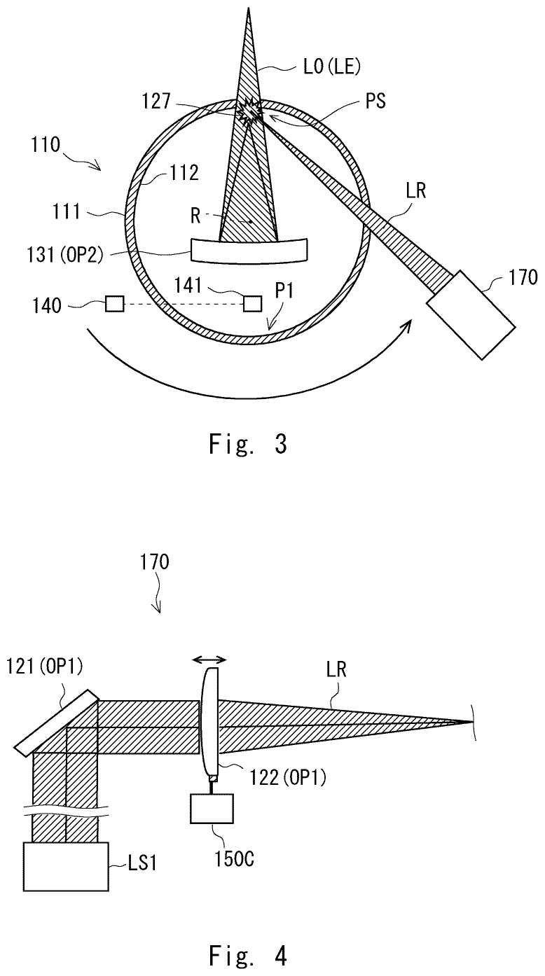

FIG. 1 is a sectional view illustrating a light source apparatus 100 according to the first embodiment. FIG. 2 is a perspective view illustrating a container 111 functioning as a target holding unit 110 in the light source apparatus 100 according to the first embodiment. FIG. 3 is a plan view illustrating the light source apparatus 100 according to the first embodiment. In FIG. 3, several members are omitted. As illustrated in FIGS. 1 to 3, the light source apparatus 100 includes a target holding unit 110, an input optical system 120, an output optical system 130, an acquiring unit 140, a sensor 141, a driving unit 150, and a control unit 160. In FIG. 1, a driving unit 150A is connected to a mirror 121, and a driving unit 150B is connected to a collector mirror 131. However, the driving units do not always need to be connected to all of these optical members. The control unit 160 is connected to only several members to prevent the figure from becoming complicated. However, the control unit 160 may be connected to other members. The control unit 160 is a control apparatus including one or a plurality of processors (processing apparatuses). The processor is connected to a memory (not illustrated), and controls operations performed by the light source apparatus 100 by loading a computer program from the memory and executing the loaded program. Details of this control will be described later.

Note that as the processor, as an example, one of a CPU (Central Processing Unit), an MPU (Micro Processing Unit), an FPGA (Field-Programmable Gate Array), a DSP (Digital Signal Processor), and an ASIC (Application Specific Integrated Circuit) may be used, or two or more of them may be used in parallel.

The memory is composed of a volatile memory, a non-volatile memory, or a combination thereof. The number of memories is not limited to one, and instead a plurality of memories may be provided. Note that the volatile memory may be, for example, a RAM (Random Access Memory) such as a DRAM (Dynamic Random Access Memory) or an SRAM (Static Random Access Memory). The non-volatile memory may be, for example, a ROM (Read Only Memory) such as a PROM (Programmable Random Only Memory) or an EPROM (Erasable Programmable Read Only Memory), a flash memory, or an SSD (Solid State Drive).

The memory is used to store one or more instructions. Note that one or more instructions are stored as a program(s) in the memory. The processor can perform the processing described in embodiments below by loading these programs from the memory and executing them. The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

Note that in addition to the memory provided outside the processor, the memory may include a memory incorporated into the processor. Further, the memory may also include a storage disposed remotely from the processor. In this case, the processor can access the memory through an I/O (input/output) interface.

As described above, one or a plurality of processors included in the light source apparatus 100 execute one or a plurality of programs including a set of instructions for causing a computer to perform an algorithm described with reference to the drawings. By executing the programs, information processing described hereinafter can be carried out.

The target holding unit 110 holds a target material 112. The target holding unit 110 includes a container 111 such as a crucible. The container 111 can hold thereinside a metal which is in a liquid state (i.e., a molten metal) by heating it from a solid state. Hereinafter, a metal in a liquid state is also referred to as a molten metal. The container 111 holds the target material 112 such as molten metal that generates plasma 127 with irradiation of excitation light LR. The excitation light LR is, for example, laser light including IR (Infrared) light.

Note that the target holding unit 110 is not limited to the container 111 and may be a cylindrical drum. In that case, the target holding unit 110 holds the target material 112 by fixing solid, which becomes the target material 112, such as xenon (Xe) frozen on the surface of the drum.

The target material 112 may include molten metal. Note that the target material 112 is not limited to the molten metal held by the container 111 and may be solid metal, droplets, or the like if the target material 112 is a substance that generates the plasma 127 with irradiation of the excitation light LR. The molten metal is, for example, melted tin (Sn) or lithium (Li) but is not limited to tin and lithium if the molten metal generates the plasma 127 with irradiation of the excitation light LR.

The container 111 has a rotation axis R and rotates centering on the rotation axis R. The container 111 has, for example, a cylindrical shape with one opening closed. A closed portion of the container 111 is referred to as bottom 113. A cylindrical portion of the container 111 is referred to as cylindrical section 114. The surface on the inner side of the bottom 113 is referred to as bottom surface 115. The inner surface of the cylindrical section 114 is referred to as inner wall surface 116A, and the outer surface of the cylindrical section 114 is referred to as outer wall surface 116B. A groove 117 may be formed in a joining portion of the bottom 113 and the cylindrical section 114. Note that the container 111 may include a shape other than the above if the container 111 can hold the molten metal.

The target holding unit 110 supports the target material 112 on the inner wall surface 116A of the container 111 by a centrifugal force. The inner wall surface 116A formed so as to surround the rotation axis R may include a cylindrical portion having a constant distance to the rotation axis R or may include a cone-shaped portion further expanded to the outer side upward. For example, the cone-shaped portion of the inner wall surface 116A may be connected to the groove 117.

The light source apparatus 100 may include a heater 118 and a debris shield 119 in addition to the target holding unit 110. The target material 112 such as molten metal can be formed inside the container 111 by heating by the heater 118. The debris shield 119 is disposed in an opening 111a of the container 111 so as to cover the target material 112.

The target material 112 also rotates around the rotation axis R according to the rotation of the container 111 around the rotation axis R. As illustrated in FIG. 3, for example, the target material 112 located, at time t1, in a position P1 facing the sensor 141 moves to an irradiation position PS at time t2 according to the rotation of the container 111. In this way, according to the movement (that is, the rotational movement) of the target holding unit 110, the target holding unit 110 moves the target material 112 to the irradiation position PS where the target material 112 is irradiated with the excitation light LR.

The input optical system 120 includes a first optical member OP1. The first optical member OP1 irradiates the target material 112 with the excitation light LR. The first optical member OP1 includes, for example, at least one of a mirror 121 and a focus adjusting mechanism 170. Note that the first optical member OP1 is not limited to the mirror 121 and the focus adjusting mechanism 170 as long as it is an optical member that irradiates the target material 112 with the excitation light LR. The first optical member OP1 may be a laser LS1 that generates the excitation light LR.

The first optical member OP1 irradiates the target material 112 with the excitation light LR at an angle inclined from an axis perpendicular to the surface of the target material 112. Specifically, for example, the first optical member OP1 applies the excitation light LR at an incident angle inclined toward the surface at the irradiation position PS to which the excitation light LR is applied. By applying the excitation light LR at an inclined angle as described above, the influence of debris on the optical members including the collector mirror 131 can be suppressed. The reason why the influence of debris on the optical members such as the collector mirror 131 can be suppressed will be explained hereinafter.

When the excitation light LR is applied from the direction perpendicular to the surface of the target material 112, debris are scattered in all directions around the direction perpendicular to the surface. Then, debris may adhere to the collector mirror 131, which faces the irradiation position PS. In contrast, when the excitation light LR is applied at an incident angle inclined toward an area ahead of the irradiation position PS with respect to the direction of the movement of the target holding unit 110, that is, when the excitation light LR is applied from a direction having an incident angle component inclined toward an area ahead in the plane perpendicular to the rotation axis R, the angular velocity in the rotational direction of the container 111 is added to the velocity in the directions in which debris are scattered. Therefore, it is possible to scatter more debris in the reflection direction of the excitation light LR. In this way, the influence of debris on the optical members such as the collector mirror 131 can be suppressed.

The mirror 121 reflects, for example, the excitation light LR generated by the laser LS1 to the irradiation position PS of the target material 112. The mirror 121 may include a mirror such as a piezo steering mirror. Note that, the mirror 121 is not limited to the piezo steering mirror and may include a Galvano mirror, a polygon mirror, and the like if the mirror 121 can reflect the excitation light LR to the target material 112. A condensing lens 122 (which will be described later) included in the focus adjusting mechanism 170 condenses the excitation light LR at the irradiation position PS on the target material 112.

The light source apparatus 100 may include the laser LS1 which is a laser generator for generating excitation light LR. On the other hand, the light source apparatus 100 may introduce, into the light source apparatus 100, the excitation light LR from the laser LS1 installed separately from the light source apparatus 100 on the outside of the light source apparatus 100. The excitation light LR is, for example, laser light including IR light. The excitation light LR may irradiate the target material 112 according to oscillation and stop of control of the control unit 160. For example, the excitation light LR is reflected by the mirror 121 and condensed by the condensing lens disposed inside the focus adjusting mechanism 170. Accordingly, the excitation light LR irradiates the target material 112.

The output optical system 130 includes a second optical member OP2. The second optical member OP2 extracts, from the light source apparatus 100, light L0 generated by irradiating the target material 112 with the excitation light LR. The second optical member OP2 includes, for example, the collector mirror 131. Note that the second optical member OP2 is not limited to the collector mirror 131 if the second optical member OP2 is an optical member that extracts light L0 generated by irradiating the target material 112 with the excitation light LR. The second optical member OP2 may be a second collector mirror (not illustrated) that further reflects the light L0 reflected by the collector mirror 131.

The collector mirror 131 reflects the light L0 generated from the target material 112 by the irradiation of the excitation light LR. The collector mirror 131 reflects, for example, EUV (Extreme Ultraviolet Lithography) light LE generated by the irradiation of the excitation light LR. That is, the light L0 may include the EUV light LE. The EUV light LE is generated from the plasma 127 generated by irradiating the target material 112 with the excitation light LR. The EUV light LE generated from the plasma 127 generated by the target material 112 is emitted to an optical apparatus such as an inspection apparatus as illumination light. Thus, the illumination light includes the EUV light LE generated from the plasma 127.

The acquiring unit 140 acquires a surface position of the target material 112. The acquiring unit 140 is connected to the sensor 141 and acquires, from the sensor 141, a surface position of the target material 112 measured by the sensor 141. The acquiring unit 140 acquires a surface position of the target material 112 in the irradiation position PS where the excitation light LR irradiates the target material 112. The acquiring unit 140 may acquire a surface position measured by the sensor 141 in the irradiation position PS or, as explained below, may predict a surface position in the irradiation position PS from a surface position measured by the sensor 141 in a peripheral position. The acquiring unit 140 may predict the surface position of the target material 112 considering a tilt with respect to the rotation axis and vibration of the target holding unit 110.

The acquiring unit 140 may be a separate body separated from the sensor 141 or may be integrated with the sensor 141. Specifically, the sensor 141 may include, for example, a displacement meter, a high-speed camera, a low-speed camera, a quadripartite PD (Photo Diode), and a TDI (Time Delay Integration) camera. The acquiring unit 140 may combine other sensors with the sensor 141 such as the displacement meter to thereby acquire the surface position of the target material 112. Accordingly, the other sensors can supplement phase information that the sensor 141 such as the displacement meter cannot easily acquire.

The acquiring unit 140 may acquire the surface position of the target material 112 as a relative position to the second optical member OP2. Specifically, the acquiring unit 140 may acquire the surface position in the irradiation position PS of the target material 112 as the relative position to the second optical member OP2 or may acquire the surface position in the peripheral position as the relative position to the second optical member OP2. The acquiring unit 140 may acquire the surface position of the target material 112 based on the distance from the sensor 141 to the surface of a liquid surface of molten metal. Further, the acquisition unit 140 may acquire the surface position of the target material 112 based on the thickness of the liquid surface of the molten metal from the inner wall surface 116A. Note that, when the target material 112 is solid metal fixed to a cylindrical drum, the acquiring unit 140 may acquire the surface position of the target material 112 based on a tilt and a vibration amount of the drum besides the thickness of the surface of the solid metal from the upper surface (the uppermost surface) of the drum.

The acquiring unit 140 may acquire a surface position in a peripheral position other than the irradiation position PS. The peripheral position includes a portion other than the irradiation position PS on the inner wall surface 116A of the container 111. The acquiring unit 140 may predict the surface position of the irradiation position PS from the surface position in the peripheral position acquired from the sensor 141. Specifically, the acquiring unit 140 predicts the surface position in the irradiation position PS from a surface position in a position on the near side of the irradiation position PS with respect to the direction of the movement of the target holding unit 110. At this time, considering moving speed (rotating speed) of the target holding unit 110, it is possible to predict the surface position in the irradiation position PS at a point in time (an irradiation point in time) when the excitation light reaches the irradiation position PS. The acquiring unit 140 predicts the surface position in the irradiation position PS in this way to thereby acquire the surface position in the irradiation position PS.

If the sensor 141 is disposed at a position facing the irradiation position PS so that the position of the surface of the irradiation position PS can be measured and acquired, there is a risk that the sensor 141 may be affected by debris. Further, since the plasma 127 is generated at the irradiation position PS, there is also a risk that the position of the surface cannot be accurately acquired. Therefore, the sensor 141 is disposed so as to face a peripheral area away from the irradiation position PS. In this way, the influence of debris can be suppressed and the accuracy of the measurement of the position of the surface can be improved. For example, the sensor 141 may be disposed so as to face a position P1 located on the opposite side of the irradiation position PS with respect to the rotation axis R. Note that if the influence of debris can be reduced, the sensor 141 may be disposed so as to face a peripheral area other than the position P1.

FIG. 4 shows an example of the focus adjusting mechanism 170 in the light source apparatus 100 according to the first embodiment. As illustrated in FIG. 4, the focus adjusting mechanism 170 includes the condensing lens 122 and a driving unit 150C. In FIG. 4, a driving unit 150C is connected to the condensing lens 122.

The condensing lens 122 condenses the excitation light LR reflected by the mirror 121 at the irradiation position PS of the target material 112. By having the control unit 160 control the driving unit 150C, the condensing lens 122 moves in either the front direction (i.e., toward the light-incoming side) or the rear direction (i.e., toward the light-exiting side) on the optical path of the laser light. In this way, the laser light output from the laser LS1 can be defocused as will be described later.

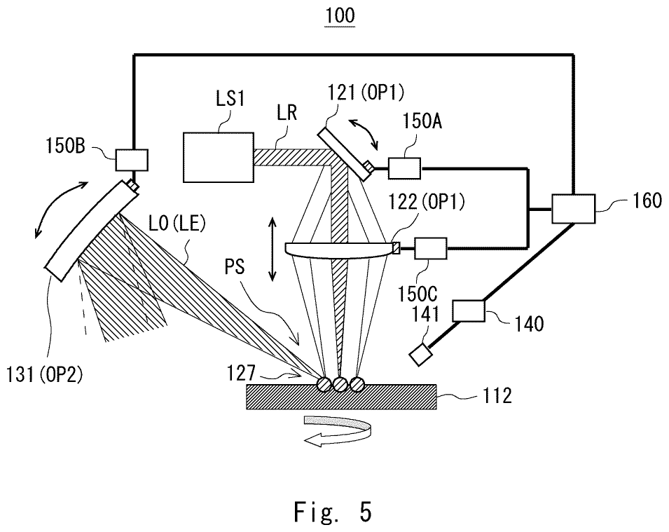

FIG. 5 shows the acquisition unit 140, the driving units 150, and the control unit 160 in the light source apparatus 100 according to the first embodiment. As explained above, the position of the sensor 141 is not limited to the position facing the irradiation position PS and may be a position facing the peripheral position such as the position P1. As illustrated in FIG. 5, the driving units 150A to 150C change the position of the focusing point of at least one of the first and second optical members OP1 and OP2. Each of the driving units 150A to 150C is, for example, an actuator.

The driving units 150A and 150C drive the first optical member OP1 to change an irradiation direction of the excitation light LR. For example, when the first optical member OP1 is the mirror 121, the driving unit 150A swings an angle of the mirror 121 with respect to the excitation light LR to perform beam scan. Specifically, the driving unit 150A changes a reflection surface of the mirror 121 such that the excitation light LR scans the surface of the target material 112 in a predetermined direction.

When the mirror 121 is a piezo steering mirror, the driving unit 150A may include a driving mechanism provided in the piezo steering mirror. When the mirror 121 is a Galvano mirror, a polygon mirror, and the like, the driving unit 150A may be a driving mechanism provided in the Galvano mirror, the polygon mirror, and the like. Note that, when there is another actuator having a short response time and good controllability, the driving unit 150A may be the actuator.

The plasm 127 is generated in the irradiation position PS where the excitation light LR irradiates the target material 112. The generated plasma 127 is observed as a bright spot. The driving unit 150A drives the mirror 121 to fluctuate an optical axis of the excitation light LR and fluctuates the position of a focusing point. Accordingly, the driving unit 150A moves the bright spot at high speed to perform beam shaving. Thus, when the optical apparatus is an inspection apparatus, it is possible to improve uniformity and availability on a detector of the inspection apparatus. The driving unit 150A may cause the position of the focusing point to move in two axial directions on the surface of the target material 112 in the irradiation position PS.

The control performed by the control unit 160 in the present disclosure will be described hereinafter. The light source apparatus 100 or the optical apparatus including the light source apparatus 100 (an example will be described later) performs an operation(s) related to one operation mode among a plurality of operation modes under the control of the control unit 160. The control unit 160 can switch the operation for the first mode and the operation for the second mode, which are examples of the plurality of operation modes, and makes the light source apparatus 100 or the optical apparatus perform the operation. However, the plurality of operation modes may include operation modes other than the first and second modes. The first mode is a mode in which the light source apparatus 100 generates plasma by irradiating the molten target material 112 with excitation light LR emitted from the laser LS1, and by doing so, generates light. The generated light may be EUV light LE, and the generated light may be used as illumination light for illuminating an object (e.g., a sample 500 described later). The first mode is a mode in which the optical apparatus illuminates the object (the sample 500 described later) by using, as the illumination light, the light which is generated as the light source apparatus 100 irradiates the molten target material 112 with the excitation light LR emitted from the laser LS1. Details of this operation are as described above.

The second mode is a mode in which the light source apparatus 100 changes the target material 112 from a solid state to a molten state by irradiating at least one of the target holding unit 110 holding the target material 112 or the target material 112 in the solid state with the laser light (hereinafter, also referred to as heating laser light) emitted from the laser LS1. In the second mode, the object to be irradiated with the heating laser light emitted from the laser LS1, i.e., the object to be directly heated by the heating laser light (hereinafter, also referred to as the object to be heated), may be the target material 112 or a part of the container 111 including the inside or the outer periphery of the container 111. For example, in the case where the container 111 rotates around the rotation axis R, the control unit 160 may control the laser LS1 so as to apply the heating laser light to the position of the container 111 which is shifted from the position where the target material 112 is held in the rotation direction.

In this process, the control unit 160 may control the laser LS1 so that the peak power density of the heating laser light in the second mode becomes smaller than that of the excitation light LR in the first mode. In the first mode, it is necessary to generate high-temperature plasma, so that it is necessary to increase the peak power density of the laser light. However, in the second mode, it is sufficient if the amount of heat required to melt the target material 112 is given thereto, so that the peak power density of the laser light can be reduced compared to that in the first mode.

The control unit 160 can perform the below-shown processes to adjust the peak power density of the laser light output from the laser LS1 in the first and second modes. Note that as long as the peak power density of the heating laser light in the second mode becomes smaller than that of the excitation light LR in the first mode, the control unit 160 may perform both processes (i) and (ii), or may perform only one of them.

(i) The control unit 160 may set the irradiation state of the heating laser light for the target holding unit 110 in the second mode to a defocus state compared to the irradiation state of the excitation light LR for the target material 112 in the first mode. The defocus state refers to a state in which the laser light is out of focus for the object to be irradiated with the laser light. That is, the spot diameter of the heating laser light applied to the object to be heated in the second mode is larger than that of the excitation light LR applied to the target material 112 in the first mode. Further, the distance between the focal point of the heating laser light and the object to be heated in the second mode is larger than the distance between the focal point of the excitation light LR and the target material 112 in the first mode. When the mode is switched from the first mode to the second mode, the control unit 160 controls the operation of the driving unit 150C illustrated in FIG. 4 and thereby moves the condensing lens 122 in either the front direction (i.e., toward the light-incoming side) or the rear direction (i.e., toward the light-exiting side) on the optical path. In this way, the control unit 160 can move the position of the focal point of the laser light output from the laser LS1 and thereby set the irradiation state of the heating laser light in the second mode to the defocus state.

(ii) The control unit 160 may set the peak power itself of the heating laser light in the second mode to a value smaller than that of the excitation light LR for the target material 112 in the first mode. For example, by adjusting the pulse width W1 of the excitation light LR in the first mode and the pulse width W2 of the heating laser light in the second mode so that a relation W1<W2 holds, the control unit 160 can set the peak power itself of the heating laser light in the second mode a value smaller than that of the excitation light LR for the target material 112 in the first mode even when the pulse energy is substantially the same in both modes.

Here, the peak power density is represented by D; the peak power is represented by PP; and the area (i.e., the size) of the irradiation spot of the laser light is represented by M. Then, they may be adjusted so that a relationship D=PP/M holds. Therefore, the control unit 160 can make the peak power densities in the first and second modes different from each other by controlling the peak power and/or the area of the irradiation spot of the laser light in the above-described manner. When the area of the irradiation spot of the laser light is small, the light is in an in-focus (focused) state, and when the area of the irradiation spot of the laser light is large, the light is in an out-of-focus (defocused) state. Therefore, making the laser light more defocused under the control of the control unit 160 is equivalent to making the area of the irradiation spot of the laser light larger.

### <Light Source Control Method>

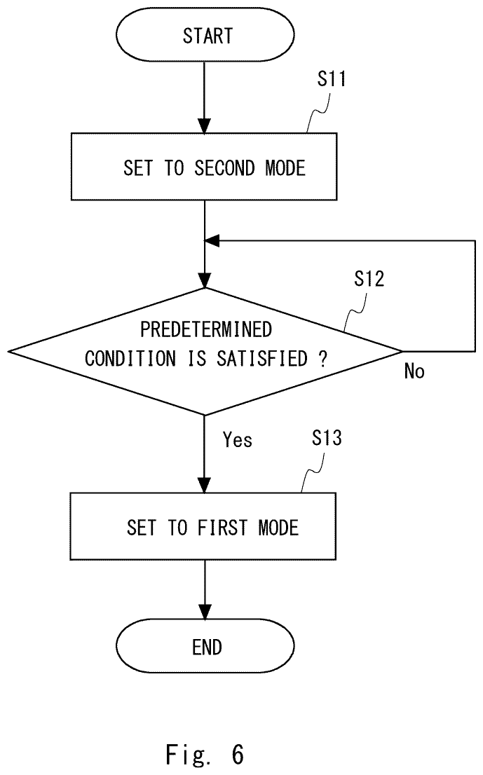

Next, a method for controlling an operation mode will be described with reference to FIG. 6. FIG. 6 is a flowchart showing an example of a method for controlling an operation mode according to the first embodiment. Firstly, as shown in the step S11, the control unit 160 sets the operation mode to the second mode. Next, as shown in the step S12, the control unit 160 determines whether or not the optical apparatus satisfies a predetermined condition. When the optical apparatus does not satisfy the condition, the control unit 160 keeps the setting of the operation mode, which is the second mode, and makes a determination in the step S12 again. When the optical apparatus satisfies the condition, the control unit 160 sets the operation mode to the first mode as shown in the step S13.

Note that when the operation mode is the first mode and the control unit 160 determines that a predetermined condition different from the condition used in the step S12 is satisfied, the control unit 160 may change the operation mode to the second mode. Further, when the operation mode is the first or second mode and the control unit 160 determines that the optical apparatus satisfies a certain condition, the control unit 160 may change the operation mode to a third mode, which is neither of the first and second modes.

An example of the predetermined condition used in the step S12 is shown below. The control unit 160 may switch the operation mode from the second mode to the first mode when the position of the plasma, which is generated by irradiating the target material 112 with the heating laser light, coincides with a predetermined position (or based on a fact that the position of the plasma coincides with the predetermined position) in the second mode. The predetermined position refers to a position where the optical path of light L0 generated by the plasma is in a direction suitable for the purpose of the light L0 (e.g., a position where the optical path is in a direction suitable for illuminating the sample 500, which is the object, with the light L0), and is a position stored in advance in a memory. The control unit 160 determines, when a sensor 141 observes generated plasma 127 as a bright spot, whether or not the observed bright spot coincides with the predetermined position.

As an example of the predetermined condition used in the step S12, the control unit 160 may switch the operation mode from the second mode to the first mode when it has determined that the target material 112 has been melted in the second mode (or based on a fact that it has determined that the target material 112 has been melted). For example, when the sensor 141 photographs the target material 112, it is possible to determine whether or not the target material 112 has been melted by having the control unit 160 analyze the photographed image. In the case where the brightness of the target material 112 in the photographed image changes between the liquid state and the solid state, the control unit 160 may determine whether or not the brightness of the target material 112 over the entire target material 112 or in a predetermined area on the target material 112 is the same as the brightness thereof in the liquid state in the photographed image, and thereby determine whether or not the target material 112 has been melted. The control unit 160 can make a similar determination not only for the brightness in the photographed image but also for hue and/or chroma in the photographed image.

Further, a sensor (e.g., a non-contact sensor) capable of measuring the temperature of the target material 112 or the target holding unit 110 may be provided in the light source apparatus 100. When the temperature measured by the sensor is equal to or higher than a predetermined threshold, the control unit 160 determines that the target material 112 has been melted.

The control unit 160 may switch the operation mode from the second mode to the first mode when a predetermined switching condition is satisfied. The predetermined switching condition may include, as described above, a condition that the position of the plasma generated by irradiating the target material 112 with the heating laser light coincides with a predetermined position. Further, the predetermined switching condition may include, as described above, a condition that it is determined that the target material 112 has been melted. Further, the predetermined switching condition may include a condition that both the condition that it is determined that the target material 112 has been melted and the condition that the position of the plasma generated by irradiating the target material 112 with the heating laser light coincides with the predetermined position are satisfied.

Note that, as described above, the control unit 160 can adjust the peak power density of the laser light when it has switched the operation mode from the second mode to the first mode.

### <Optical Apparatus>

Next, the optical apparatus is explained. The optical apparatus is explained using an inspection apparatus as an example of the optical apparatus.

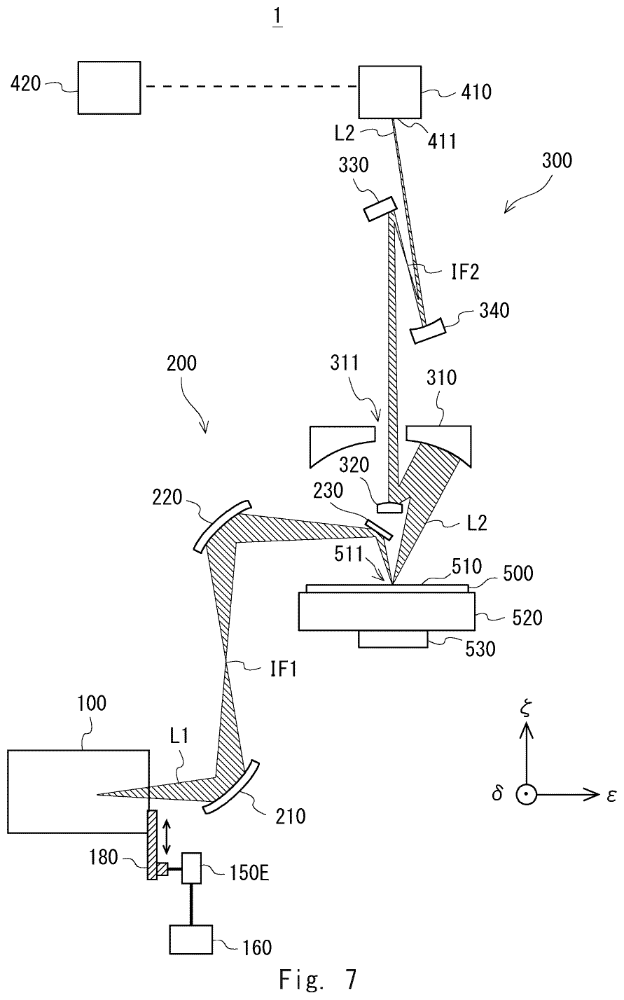

FIG. 7 is a configuration diagram illustrating an inspection apparatus 1 including the light source apparatus 100 according to the first embodiment. As illustrated in FIG. 7, the inspection apparatus 1 includes an illumination optical system 200, an inspection optical system 300, a detector 410, and an image processing unit 420. Note that the inspection apparatus 1 may further include the light source apparatus 100. The inspection apparatus 1 is an apparatus that inspects a defect and the like of a sample 500 using, as the illumination light L1, the light L0 generated by the light source apparatus 100. The sample 500 is, for example, an EUV mask. Note that the sample 500 is not limited to the EUV mask and may be a semiconductor substrate or the like.

The illumination optical system 200 includes an ellipsoidal mirror 210, an ellipsoidal mirror 220, and a drop-in mirror 230. The inspection optical system 300 includes a concave mirror with hole 310, a convex mirror 320, a plane mirror 330, and a concave mirror 340. The concave mirror with hole 310 and the convex mirror 320 configure a Schwarzschild enlarging optical system.

The light source apparatus 100 generates illumination light L1. The illumination light L1 includes, for example, the EUV light LE having a wavelength of 13.5 nm that is the same as an exposure wavelength of the EUV mask to be the sample 500. Note that the illumination light L1 may include light other than the EUV light.

In the light source apparatus 100, a shutter 180 is provided near the point where the generated illumination light L1 is emitted. The shutter 180 is connected to the driving unit 150E, and its opening/closing is controlled as a result of the operation of the driving unit 150E. The shutter 180 is provided on the optical path between the target material 112 and the sample 500, which is the object. Therefore, when the shutter 180 is in the closed state, no light is emitted from the light source apparatus 100. On the other hand, when the shutter 180 is in the opened state, light can be emitted from the light source apparatus 100.

The control unit 160 controls the opening/closing of the shutter 180 by controlling the driving of the driving unit 150E. In the first mode, the control unit 160 can illuminate the sample 500 with the illumination light L1 by bringing the shutter 180 into the opened state. On the other hand, in the second mode, the control unit 160 does not illuminate the sample 500 with the light emitted from the light source apparatus 100 by driving the shutter 180 and thereby bringing it into the closed state. Therefore, even if light originating from the target material 112 is generated in the second mode, the control unit 160 can prevent the light from reaching the sample 500.

When the shutter 180 is in the opened state, the illumination light L1 generated in the light source apparatus 100 is reflected by the ellipsoidal mirror 210. The illumination light L1 reflected by the ellipsoidal mirror 210 travels while being narrowed and is condensed at a convergent point IF1. Thus, the ellipsoidal mirror 210 reflects, as convergent light, the illumination light L1 generated from the light source apparatus 100. The convergent point IF1 is a position conjugate with an upper surface 510 of the sample 500 such as the EUV mask and a detection surface 411 of the detector 410.

After passing the convergent point IF1, the illumination light L1 travels while expanding and is made incident on a reflection mirror such as the ellipsoidal mirror 220. Thus, the illumination light L1 reflected by the ellipsoidal mirror 210 is made incident on the ellipsoidal mirror 220 as divergent light via the convergent point IF1. The illumination light L1 made incident on the ellipsoidal mirror 220 is reflected by the ellipsoidal mirror 220, travels while being narrowed, and is made incident on the drop-in mirror 230. That is, the ellipsoidal mirror 220 reflects the incident illumination light L1 as convergent light. The ellipsoidal mirror 220 makes the illumination light L1 incident on the drop-in mirror 230. The drop-in mirror 230 is disposed right above the EUV mask. The illumination light L1 made incident on the drop-in mirror 230 and reflected is made incident on the sample 500. Thus, the drop-in mirror 230 makes the illumination light L1 incident on the sample 500 by reflecting, to the sample 500, the illumination light L1 reflected by the ellipsoidal mirror 220.

The ellipsoidal mirror 220 condenses the illumination light L1 on the sample 500. The illumination optical system 200 is installed to form an image of the light source apparatus 100 on the upper surface 510 of the sample 500 when the illumination light L1 illuminates the sample 500. Thus, the illumination optical system 200 is critical illumination. As explained above, the illumination optical system 200 illuminates the sample 500 such as the EUV mask using the critical illumination by the illumination light L1 generated by the light source apparatus 100.

The sample 500 is disposed on a stage 520. Note that a plane parallel to the upper surface 510 of the sample 500 is referred to as a de plane, and a direction perpendicular to the 88 plane is referred to as a ζ-axis direction. The illumination light L1 is incident on the sample 500 in a direction inclined from the ζ-axis direction. That is, the illumination light L1 is made obliquely incident and illuminates the sample 500.

The stage 520 is a three-dimensional driving stage including a driving unit 530. The driving unit 530 can illuminate a desired region on the sample 500 by moving the stage 520 on the de plane. Further, the driving unit 530 can adjust the focus by moving the stage 520 in the ζ-axis direction.

The illumination light L1 from the light source apparatus 100 illuminates an inspection region of the sample 500. The inspection region illuminated by the illumination light L1 is, for example, a 0.5 mm square. Note that the inspection region is not limited to the 0.5 mm square. The illumination light L1 is incident on the sample 500 in a direction inclined from the ζ-axis direction. Light from the sample 500 illuminated by the illumination light L1 is made incident on the concave mirror with hole 310. In the following explanation, the light from the sample 500 illuminated by the illumination light L1 is explained as reflected light L2. Note that the light made incident on the concave mirror with hole 310 from the sample 500 is not limited to the reflected light L2 and may include diffracted light or the like. The reflected light L2 reflected by the sample 500 is made incident on the concave mirror with hole 310. A hole 311 is provided in the center of the concave mirror with hole 310. The concave mirror with hole 310 condenses the reflected light L2 from the sample 500 and reflects the condensed reflected light L2 as convergent light.

The reflected light L2 reflected by the concave mirror with hole 310 is made incident on the convex mirror 320. The convex mirror 320 reflects the reflected light L2 reflected by the concave mirror with hole 310 toward the hole 311 of the concave mirror with hole 310. The reflected light L2 having passed through the hole 311 is made incident on the plane mirror 330. The plane mirror 330 makes the reflected light L2 reflected by the convex mirror 320 incident as convergent light through the hole 311 of the concave mirror with hole 310. The reflected light L2 made incident on the plane mirror 330 is reflected by the plane mirror 330. The reflected light L2 reflected by the plane mirror 330 travels while being narrowed and is condensed at a convergent point IF2. Thus, the plane mirror 330 reflects the incident reflected light L2 as convergent light. The convergent point IF2 may be referred to as aperture stop. The convergent point IF2 is a position conjugate with the upper surface 510 of the sample 500 and the detection surface 411 of the detector 410.

After passing the convergent point IF2, the reflected light L2 travels while expanding and is made incident on the concave mirror 340. Thus, the reflected light L2 reflected by the plane mirror 330 as the convergent light is made incident on the concave mirror 340 via the convergent point IF2 as divergent light. The concave mirror 340 reflects the incident reflected light L2 to the detector 410 as convergent light. The reflected light L2 reflected by the concave mirror 340 is detected by the detector 410. As explained above, the inspection optical system 300 inspects the sample 500, which is the inspection target, with the illumination light L1 acquired from the output optical system 130 of the light source apparatus 100. That is, the inspection optical system 300 condenses the reflected light L2 from the sample 500 illuminated by the illumination light L1 and guides the condensed reflected light L2 to the detector 410.

The detector 410 may include a TDI (Time Delay Integration) sensor. The detector 410 receives light from the sample 500 illuminated by the illumination light L1. A region on the sample 500 detected by the detector 410 is referred to as visual field region 511. The detector 410 receives the reflected light L2 from the visual field region 511 illuminated by the illumination light L1. The visual field region 511 may be included in the inspection region illuminated by the illumination light L1. The detector 410 acquires image data of the sample 500 such as the EUV mask. When the detector 410 includes a TDI sensor, the detector 410 includes a plurality of imaging elements linearly disposed side by side in one direction. The imaging elements are, for example, CCDs (Charge Coupled Devices). Note that the imaging elements are not limited to the CCDs.

The image data of the sample 500 acquired by the detector 410 is output to the image processing unit 420 and processed in the image processing unit 420. The image processing unit 420 may be, for example, a server apparatus or an information processing apparatus such as a personal computer.

The reflected light L2 includes information concerning a defect or the like of the sample 500. Regular reflected light of the illumination light L1 made incident on the sample 500 from a direction tilted with respect to the Z-axis direction is detected by the inspection optical system 300. When a defect is present in the sample 500, the defect is observed as a dark image. Such an observation method is referred to as bright field observation. Note that the inspection apparatus 1 may make the illumination light L1 incident on the sample 500 from the Z-axis direction and cause the inspection optical system 300 to detect the illumination light L1. When a defect is present in the sample 500, the defect is observed as a bright image. Such an observation method is referred to as dark field observation.

As explained above, the inspection apparatus 1 in the present embodiment includes the light source apparatus 100 explained above and the inspection optical system 300 that inspects an inspection target with the light L0 acquired from the output optical system 130. Note that the inspection apparatus 1 is explained as the optical apparatus. However, the optical apparatus may be an exposure apparatus. For example, the exposure apparatus includes the light source apparatus 100 explained above and an exposure optical system that exposes an exposure target with the light L0 acquired from the output optical system 130. The control unit 160 may drive the driving unit 150 such that the light L0 scans an exposure region in the exposure target.

As described above, the control unit 160 determines one mode to be executed from among a plurality of operation modes. For example, the control unit 160 can switch the mode between the first mode in which the sample 500 is illuminated by irradiating the target material 112 with laser light and the second mode in which the target material 112 is melted by irradiating the target holding unit 110 with laser light. Therefore, the light source apparatus 100 executes the second mode under the control of the control apparatus 160, and after that, executes the first mode. In this way, it is possible to simplify, for example, the processes up to the illumination of the object, and thereby improve the efficiency of the operation of the light source apparatus 100. Further, for example, even when some target material 112 is sticking to (e.g., has been deposited on) the container 111, the sticking target material 112 is heated in advance in the second mode under the control of the control apparatus 160, so that the preparation for generating illumination light can be completed, thus making it possible to improve the efficiency of the maintenance of the light source apparatus 100.

Further, the control unit 160 may switch the opening/closing of the shutter 180 between the first and second modes. In this way, even when light originating from the target material 112 is generated in the second mode, the light hardly reaches the sample 500, thus making it possible to prevent an unexpected erroneous inspection from occurring.

Note that the shutter 180 may be provided not in the light source apparatus 100 but on the optical path up to the visual field region 511 in the illumination optical system 200. As the control unit 160 of the light source apparatus 100 or the control unit of the inspection apparatus 1 controls the shutter 180, the opening/closing of the shutter 180 in the first and second modes is controlled in a manner similar to the above-described manner.

The shutter 180 is an example of adjustment means for preventing light generated in the light source apparatus 100 from propagating to the sample 500, which is the object. As adjustment means other than the shutter 180, for example, an optical element such as a mirror or an actuator for changing the position/posture of a stage on which the sample 500 is placed may be provided in the inspection apparatus 1. The control unit 160 drives the optical element or the actuator in the second mode. In this way, even when light originating from the target material 112 is generated in the second mode, it is possible to prevent the light from propagating to the sample 500.

Further, the control unit 160 may also set the peak power density of the laser light in the second mode a value smaller than that in the first mode. When the peak power density in the second mode is large, if a target material 112 which was once melted and then became a solid again is sticking to the target holding unit 110, plasma may be generated from the target holding unit 110 and hence illumination light may be generated. However, it is possible to prevent such a situation from occurring by reducing the peak power density in the second mode.

Further, when the mode to be executed is the second mode, the control unit 160 may switch the operation mode to be executed from the second mode to the first mode when the position of plasma generated by irradiating the target material 112 with the heating laser light coincides with the predetermined position. In this way, the control unit 160 can keep the operation mode, which is the second mode, when the illumination light L1 is generated at an angle not suitable for the inspection of the sample 500, thus making it possible to obtain stable inspection results.

Further, when the control unit 160 determines that the target material 112 has been melted in the second mode, it may switch the operation mode to be executed from the second mode to the first mode. In this way, the control unit 160 can keep the mode, which is the second mode, when the illumination light L1 for the sample 500 is not generated, thus making it possible to obtain stable inspection results.

### Second Embodiment

A light source apparatus according to a second embodiment is explained. In this embodiment, a configuration of a light source apparatus having a configuration different from that of the light source apparatus according to the first embodiment will be described.

The light source apparatus may further include a laser generator (hereinafter, also referred to as a laser LS2) different from the laser LS1. The control unit 160 performs the irradiation of laser light in the first mode by controlling the laser LS1 according to the operation mode to be executed, and performs the irradiation of laser light in the second mode by controlling the laser LS2. The position to which the heating laser light is applied in the second mode is not limited to the target material 112 and the area therearound. For example, the laser LS2 may heat the container 111 and melt a solid target material 112 by applying laser light to one of the bottom 113 of the container 111, a part of the inner wall surface 116A on which the target material 112 is not held, and the outer wall surface 116B. The characteristics of the laser light applied by the laser LS2 in the second mode are the same as those described in the first embodiment.

A part of the optical path from the laser LS1 to the target material 112 and a part of the optical path from the laser LS2 to the container 111 may coincide with each other. For example, in the light source apparatus 100, a common optical element(s) such as a mirror 121 or a condensing lens 122 may be disposed on both optical paths (i.e., at the common part of both optical paths). The laser light emitted from the laser LS1 and the laser light emitted from the laser LS2 are output through the common optical element(s). Alternatively, there is no common optical element between both optical paths, and the optical paths may not overlap each other at all.

### Third Embodiment

In the second mode in the first or second embodiment, the target material 112 may not be held in the target holding unit 110. The target holding unit 110 may hold the target material 112 after its temperature reaches a temperature that is high enough to melt the target material 112. Further, the position where the target holding unit 110 holds the target material 112 in the second mode in the first or second embodiment may be different from the position where the target holding unit 110 holds the target material 112 in the first mode. The target holding unit 110 may hold the target material 112 at the holding position in the first mode after the temperature reaches a temperature that is high enough to melt the target material 112.

A program in which the operations performed by the control unit 160 of the light source apparatus 100 includes instructions or software codes that, when loaded into a computer, cause the computer to perform one or more of the functions described in the embodiments. The program may be stored in a non-transitory computer readable medium or a tangible storage medium. By way of example, and not a limitation, the non-transitory computer readable media or tangible storage media can include a RAM (Random-Access Memory), a ROM (Read-Only Memory), a flash memory, an SSD (Solid-State Drive) or other types of memory technologies, a CD-ROM (Compact Disc Read-Only Memory), a DVD (Digital Versatile Disc), a Blu-ray (Registered Trademark) disc or other types of optical disc storage, and magnetic cassettes, magnetic tape, magnetic disk storage or other types of magnetic storage devices. The program may be transmitted on a transitory computer readable medium or a communication medium. By way of example, and not a limitation, the transitory computer readable media or communication media can include electrical, optical, acoustical, or other forms of propagation signals. Transitory computer readable media or communication media can provide the program to a computer through a wired communication line (e.g., electric wires, and optical fibers) or a wireless communication line.

The following configuration is also encompassed by the technical thought of the above-described example embodiments.

### (Supplementary Note 1)

A method for controlling an optical apparatus, comprising:
a first step of illuminating an object with illumination light generated by irradiating a molten target material with laser light;
a second step of changing the target material from a solid state to a molten state by irradiating at least one of a holding unit of the target material or the target material in the solid state with laser light; and
a third step of switching the first step and the second step.

### (Supplementary Note 2)

A method for controlling a light source apparatus, comprising:
a first step of generating light by irradiating a molten target material with laser light;
a second step of changing the target material from a solid state to a molten state by irradiating at least one of a holding unit of the target material or the target material in the solid state with laser light; and
a third step of switching the first step and the second step.

### (Supplementary Note 3)

A non-transitory computer readable medium storing a program for causing an optical apparatus to perform:
a first step of illuminating an object with illumination light generated by irradiating a molten target material with laser light;
a second step of changing the target material from a solid state to a molten state by irradiating at least one of a holding unit of the target material or the target material in the solid state with laser light; and
a third step of switching the first step and the second step.

### (Supplementary Note 4)

A non-transitory computer readable medium storing a program for causing a light source apparatus to perform:
a first step of generating light by irradiating a molten target material with laser light;
a second step of changing the target material from a solid state to a molten state by irradiating at least one of a holding unit of the target material or the target material in the solid state with laser light; and
a third step of switching the first step and the second step.

### (Supplementary Note 5)

A control apparatus for an optical apparatus comprising a light source apparatus, the control apparatus including one or more processors configured to execute program instructions that cause the one or more processors to determine a mode to be executed from among a plurality of modes and cause the optical apparatus to operate in the determined mode,
wherein the plurality of modes include a first mode in which the light source apparatus irradiates laser light onto a molten target material to generate illumination light, and the optical apparatus illuminates an object using the illumination light, and a second mode in which the light source apparatus irradiates laser light onto at least one of a holding unit of the target material or the target material in a solid state to change the target material from the solid state to a molten state.

### (Supplementary Note 6)

A control apparatus for a light source apparatus, the control apparatus including one or more processors configured to execute program instructions that cause the one or more processors to determine a mode to be executed from among a plurality of modes and cause the light source apparatus to operate in the determined mode,
wherein the plurality of modes include a first mode in which the light source apparatus irradiates laser light onto a molten target material to generate light and a second mode in which the light source apparatus irradiates laser light onto at least one of a holding unit of the target material or the target material in a solid state to change the target material from the solid state to a molten state.

### (Supplementary Note 7)

A method for controlling an optical apparatus comprising a light source apparatus, the method being executed by one or more processors executing a program stored in a memory, the method comprising:
a first step of illuminating, by the optical apparatus, an object with illumination light generated by irradiating laser light onto a molten target material using the light source apparatus;
a second step of irradiating, by the light source apparatus, at least one of a holding unit of the target material or the target material in a solid state with laser light, thereby changing the target material from the solid state to a molten state; and
a third step of switching, by the one or more processors, among a plurality of steps including at least the first step and the second step.

### (Supplementary Note 8)

A method for controlling a light source apparatus, the method being executed by one or more processors executing a program stored in a memory, the method comprising:
a first step of irradiating, by the light source apparatus, laser light onto a molten target material thereby generating light;
a second step of irradiating, by the light source apparatus, at least one of a holding unit of the target material or the target material in a solid state with laser light, thereby changing the target material from the solid state to a molten state; and
a third step of switching, by the one or more processors, among a plurality of steps including at least the first step and the second step.

### (Supplementary Note 9)

A light source apparatus configured to generate light by irradiating a molten target material with laser light, the apparatus comprising:
a control unit including one or more processors configured to execute program instructions to irradiate at least one of a holding unit of the target material or the target material in a solid state with laser light, thereby changing the target material from the solid state to a molten state.

Although embodiments according to the present disclosure have been described above, the present disclosure includes various modifications without impairing the purpose and advantages thereof, and is not limited by the above-described embodiments. Further, the configurations of the first to third embodiments may be combined with one another as appropriate. The first, second and third embodiments can be combined as desirable by one of ordinary skill in the art.

What is claimed is:

1. A control apparatus for an optical apparatus comprising a light source apparatus, configured to determine a mode to be executed from among a plurality of modes and control the optical apparatus accordingly,
wherein the plurality of modes include a first mode in which the light source apparatus irradiates laser light onto a molten target material to generate illumination light, and the optical apparatus illuminates an object using the illumination light, and a second mode in which the light source apparatus irradiates laser light onto at least one of a holding unit of the target material or the target material in a solid state to change the target material from the solid state to a molten state.

2. The control apparatus according to claim 1, wherein a peak power density of the laser light in the second mode is smaller than that of the laser light in the first mode.

3. The control apparatus according to claim 2, wherein an irradiation state of the laser light in the second mode is a defocus state compared to that of the laser light in the first mode.

4. The control apparatus according to claim 2, wherein peak power of the laser light in the second mode is smaller than that of the laser light in the first mode.

5. The control apparatus according to claim 1, wherein when the mode to be executed is the second mode, the control apparatus switches the mode to be executed from the second mode to the first mode based on a fact that a position of plasma generated by the irradiation of the laser light coincides with a predetermined position.

6. The control apparatus according to claim 1, wherein when the mode to be executed is the second mode, the control apparatus switches the mode to be executed from the second mode to the first mode based on determination that the target material has been melted.

7. The control apparatus according to claim 1, wherein the light source apparatus comprises a laser generator configured to output the laser light in the first mode and the laser light in the second mode, and
wherein the control apparatus controls the laser generator according to the mode to be executed.

8. The control apparatus according to claim 1, wherein the light source apparatus comprises:
a first laser generator configured to output the laser light in the first mode;
a second laser generator configured to output the laser light in the second mode; and
an optical element through which the laser light generated by the first laser generator and the laser light generated by the second laser generator pass, and
wherein the control apparatus controls the first and second laser generators according to the mode to be executed.

9. The control apparatus according to claim 1, wherein:
the light source apparatus comprises the holding unit configured to hold the molten target material by rotating, and
the control apparatus makes the light source apparatus irradiate the molten target material held by the holding unit with the laser light when the mode to be executed is the first mode.

10. The control apparatus according to claim 1, wherein:
the optical apparatus comprises adjustment means for preventing light generated in the light source apparatus from propagating to the object, and
the control apparatus drives the adjustment means when the mode to be executed is the second mode.

11. A control apparatus for a light source apparatus, configured to determine a mode to be executed from among a plurality of modes and control the light source apparatus accordingly,
wherein the plurality of modes include a first mode in which the light source apparatus irradiates laser light onto a molten target material to generate light and a second mode in which the light source apparatus irradiates laser light onto at least one of a holding unit of the target material or the target material in a solid state to change the target material from the solid state to a molten state.

12. The control apparatus according to claim 11, wherein a peak power density of the laser light in the second mode is smaller than that of the laser light in the first mode.

13. The control apparatus according to claim 11, wherein when the mode to be executed is the second mode, the control apparatus switches the mode to be executed from the second mode to the first mode based on a fact that a position of plasma generated by the irradiation of the laser light coincides with a predetermined position.

14. The control apparatus according to claim 11, wherein when the mode to be executed is the second mode, the control apparatus switches the mode to be executed from the second mode to the first mode based on determination that the target material has been melted.

15. A light source apparatus configured to generate light by irradiating a molten target material with laser light, comprising a control unit configured to change the target material from a solid state to a molten state by irradiating at least one of a holding unit of the target material or the target material in the solid state with laser light.

16. The light source apparatus according to claim 15, further comprising the holding unit configured to hold the molten target material by rotating.
